(19) United States
(12) Patent Application Publication
(10) Pub. No.: US 2009/0193891 A1
(43) Pub. Date: Aug. 6, 2009

(54) Sensor ,Sensor Component and Method for Producing a Sensor

(76) Inventors: Dirk Ullmann, Reutlingen (DE); Harald Emmerich, Kusterdingen (DE)

Correspondence Address: KENYON & KENYON LLP, ONE BROADWAY, NEW YORK, NY, 10004, US

(21) Appl. No.: 12/083,420

(22) PCT Filed: Nov. 8, 2006
(86) PCT No.: PCT/EP2006/068239

§ 371 Date: Mar. 10, 2009

(30) Foreign Application Priority Data
Nov. 10, 2005 (DE) 10 2005 053 682.4

(51) Int. Cl. G01D 11/24; H05K 13/04

(52) U.S. Cl. 73/431; 29/428

(57) ABSTRACT

A sensor, a sensor component and a method for manufacturing a sensor are provided, in which sensors for measuring absolute values are inserted into cost-effective and technically simple plastic housings of the usual construction type, without having negative effects on the long-term stability of the absolute measuring values supplied by such sensors. In particular, parameter drifts and offsets in the parameters are induced by arranging a sensor element above an application-specific semiconductor element which evaluates the sensor's signals, and is connected to it via a flip-chip connection. Mechanical, thermal and moisture stresses are prevented and compensated for by introducing a suitable quantity of gel into the plastic housing.

### BACKGROUND OF THE INVENTION

1. Field of the Invention

The present invention relates to a sensor for measuring absolute values and a method for manufacturing such a sensor.

2. Description of Related Art

With the increasing entry of electronics into traffic technology, especially into automotive technology, there is an increase in the requirement for supporting sensors, so that safety features and comfort and convenience features in automobile construction may be further established and in an improved manner. Of particular importance in this connection are yaw-rate sensors and acceleration sensors. Control functions and steering functions, for instance, for securing the stability of an automobile may be ensured by such sensors, as is made possible, for example, by electronic stability programs (ESP), which are used extensively these days. For such programs to be able to work, appropriately reliable sensor data have to be available to them, in order for them to evaluate the current operating state of a motor vehicle and to initiate appropriately suitable control measures and steering measures.

Acceleration sensors are used especially, for instance, in the field of air bag triggering in response to a traffic accident, or a specified collision of a certain force, which trigger an air bag when a certain deceleration is detected. Another example is yaw-rate sensors which ascertain cornering speeds of a motor vehicle, and which initiate appropriately coordinated braking processes at the individual wheels, in case the electronic stability program detects a critical situation.

Sensors are frequently installed which are manufactured as micromechanical components. One example of an acceleration sensor is described in published German patent document DE 10104868. The document gives an appropriate manufacturing process for such a component.

In some of the sensor elements discussed before, which are developed as yaw-rate sensors and acceleration sensor, only relative magnitudes are ascertained and no absolute magnitudes, and the offset accuracy, that is, the accuracy with respect to a drifting of the operating parameters of the components is not considerable in the application case, because relative magnitudes are determined for the evaluation of the sensor data, and corresponding parameter shifts in the evaluation result cancel out, or do not have a strong effect. Examples for the cause of such parameter shifts are temperature fluctuations, fluctuations in the thermal coefficient of expansion of the components used, moisture penetration into the housings which, in turn, are able to influence the parameters of the sensor measurement, and tensions that occur when the sensors are installed in a housing.

Cost-effective plastic housings such as PLCC (plastic leaded chip carrier), SOIC (small outline IC), QFN and SO (small outline) have disadvantages when used in sensor applications. These housings generate interfering influences, for instance, in the form of mechanical loads which are caused by the material pairing of plastic/silicon, and the different thermal coefficients of expansion of these materials.

It is also true that disadvantageous properties of these housings negatively influence the interaction of components situated in them which work together.

This applies, for instance, to the interaction of a sensor situated in the housing and a semiconductor element that processes the measuring data of the sensor and prepares them for a subsequent evaluation. For instance, in the case of a plastic housing, a plastic material or a gel material having moisture absorption due to aging or temperature effects may be involved. Such a change in the environment may lead to parameter drifts in the outputs of the enclosed components. This applies especially with regard to heating, aging effects and hystereses.

Thus, when current technology is used on sensors that are stable to offset, if plastic packaging is used, no great demands may be made on drift stability. This applies especially to temperature, and also to the service life of the sensor element. Instead, very costly housings, such as ceramic housings, have to be used, which, in turn, make the end product more costly. As a result, there is a great demand for sensor elements that are able to be manufactured cost-effectively, particularly micromechanical elements which offer great long-term stability, practically no offset and great measuring accuracy for absolute measuring quantities, over their entire service life.

### BRIEF SUMMARY OF THE INVENTION

An object of the present invention is to provide a sensor, a sensor component and a method for producing a sensor which are able to be implemented using usual, technically simple housings that do not have the disadvantages of the known related art.

In a particularly advantageous manner, according to the sensor component according to the present invention, the sensor element and the appertaining carrier element, preferably present in the form of an appertaining evaluation electronics system in the form of an application-specific semiconductor element, are situated one above the other and are connected to each other via a short connection. In this way, the connecting paths between the active components are short, and capacitive influences, which disadvantageously influence the evaluation of the sensor data, and which connecting wires give rise to, are reduced.

In the intermediate area of the device, an elastic buffer element, especially an adhesive cushion, is advantageously situated, which fastens the sensor element and, at the same time, decouples it from mechanical surrounding influences, on account of its elastic properties.

According to one further refinement of the structure according to the present invention, the first connection is developed in flip-chip type.

Bonding wires are advantageously used only for the electrical connection of the sensor component to the outside, and this reduces complicated manufacturing steps to a minimum.

In one refinement of the sensor component according to the present invention, a subsection of the sensor element is advantageously contacted by a gel that compensates for thermal and mechanical influences in the area of the sensitive sensor element. In this way, long-term stability of the measuring results is ensured, great mechanical stability within the housing being ensured in spite of the plastic housing, because a gel uniformly distributes the mechanical and thermal requirements.

The gel advantageously also contacts the plastic housing, because in that way an optimal adjustment of thermal and mechanical requirements is made possible. The gel advantageously also contacts the carrier element, since in such a way an even better adaptation takes place of the conditions on the inside of the housing, with regard to the components present there, and the adjustment of thermal and mechanical requirements is made possible in an even more optimal fashion.

A flip-chip connection is advantageously made as a ball grid array, since ball grid arrays have proven themselves in practice and produce a good connection between components.

Constructive adhesive material is advantageously used for contacting between the sensor element and the evaluating carrier element, this conductive adhesive material being advantageously also able to be a anisotropic conductive adhesive material.

The sensor element is advantageously soldered to the carrier element using reflow soldering, since in this way no long-term influences occur in the area of the connection between the chip elements.

In one refinement of the sensor component according to the present invention, it is especially advantageous to develop the sensor element as a micromechanical sensor element, because such sensor elements measure accurately and may be manufactured cost-effectively in large quantities.

In one refinement of the sensor structure it is particularly advantageous to develop the carrier element as an application-specific semiconductor element for the preparation of sensor data of the first sensor element, since in this way the two components of the sensor may be optimally coordinated with each another, and the particular requirements of the respective components are particularly taken into account with respect to mechanical, thermal and electrical long-term stability.

In one method for producing a sensor according to the present invention, it is advantageously ensured that a highly accurately measuring structure having long-term stability is created, which is made up of a sensor element and a carrier element, preferably present in the form of an evaluating semiconductor element, advantageously, only the evaluating semiconductor element being connected to the outside via bonding wires to connecting pins of the chip housing, in spite of which a cost-effective and technically simple plastic housing being able to be used. In this connection, it is also important that the connecting paths being created between the sensitive sensor element and the appertaining evaluating semiconductor element are as short as possible, so that the sensor data are not corrupted, and a high long-term stability of the device is ensured.

In a further refinement of the manufacturing method according to the present invention, a subsection of the structure on the inside of the plastic housing is advantageously surrounded by a gel, because gels provide for a thermal and mechanical balance, and distribute the mechanical stresses uniformly, so that a great long-term stability of the sensor parameters is able to be ensured, because outer influences that might effect a drift are screened off better.

By using more or less gel and an interior space volume of the housing that is adapted to the gel quantity, it is possible to adapt the interior structure of the housing to the respective requirements of the application, by having appropriate recesses in the housing.

Only the highly sensitive sensor element may advantageously be contacted by gel, the sensor element and the region of the bonding wires, or the entire surrounding region of the sensor element, of the semiconductor element and of the bonding wires may be surrounded by the gel. To the extent that the quantity of gel on the inside of the housing increases, and the quantity of the components contacted by it there increases, one is able to achieve an improved adjustment to the environmental conditions present, and stresses are distributed and dissipated more uniformly.

In the manufacturing method according to the present invention, a flip-chip connection is advantageously used, for instance, in the form of a ball grid array, because this makes possible a more secure contacting and also the passing on of sensitive sensor signals between the sensor element and the evaluating carrier element, without the long-term stability of the connection being endangered.

Particularly advantageous is a sensor made according to a manufacturing method according to the present invention, because the manufacturing method according to the present invention makes certain that a sensor is constructed which has great long-term stability, uses a cost-effective housing and supplies accurate measuring results over its entire service life.

A refinement of the sensor is advantageously executed as an inertial sensor, since there is a great demand for them in this market segment, and they are suitable for use in the automobile field as cost-effective sensors.

### BRIEF DESCRIPTION OF THE SEVERAL VIEWS OF THE DRAWING

FIG. 1 shows a top view onto a sensor device according to the related art.

FIG. 2 shows a side view onto a sensor device according to the related art.

FIG. 3 shows a diagrammatic sketch of a sensor component according to one exemplary embodiment of the present invention.

FIG. 4 shows an exemplary embodiment of a sensor component according to the present invention.

FIG. 5 shows an additional exemplary embodiment of a sensor component according to the present invention.

FIG. 6 shows an additional exemplary embodiment of a sensor component according to the present invention.

### DETAILED DESCRIPTION OF THE INVENTION

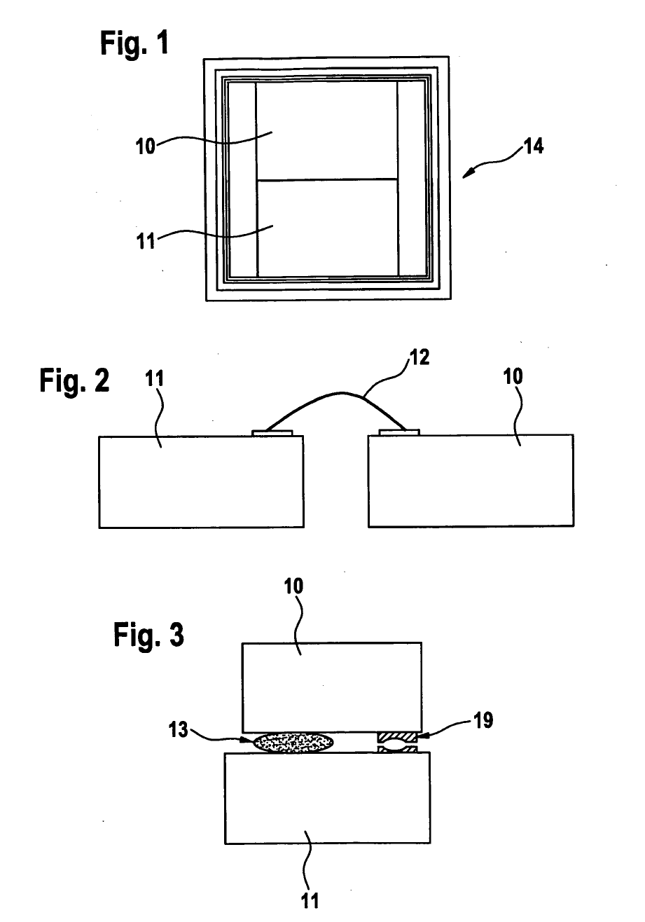

As shown in FIGS. 1 and 2, a sensor element and a semiconductor element, which is used to evaluate the information of the data measured by the sensor, are situated side by side in a common hosing. The semiconductor element in the form of an evaluation electronic system 11 is connected to sensor element 10 via one or more bonding wires 12. In this example, we show an acceleration sensor for low g ranges, in which a semiconductor component that is developed specifically for a customer, which further processes sensor data, and the sensor element was designed via surface micromechanics. Sensor element 10 conducts its measurements using capacitive evaluation, in this instance. In this regard, the connection of sensor element 10 and evaluation electronic system 11, which is established electrically via bonding wires 12, represents a disadvantage, because the bonding wires generate additional parasitic capacities and may thus have a direct influence on the behavior of the sensor.

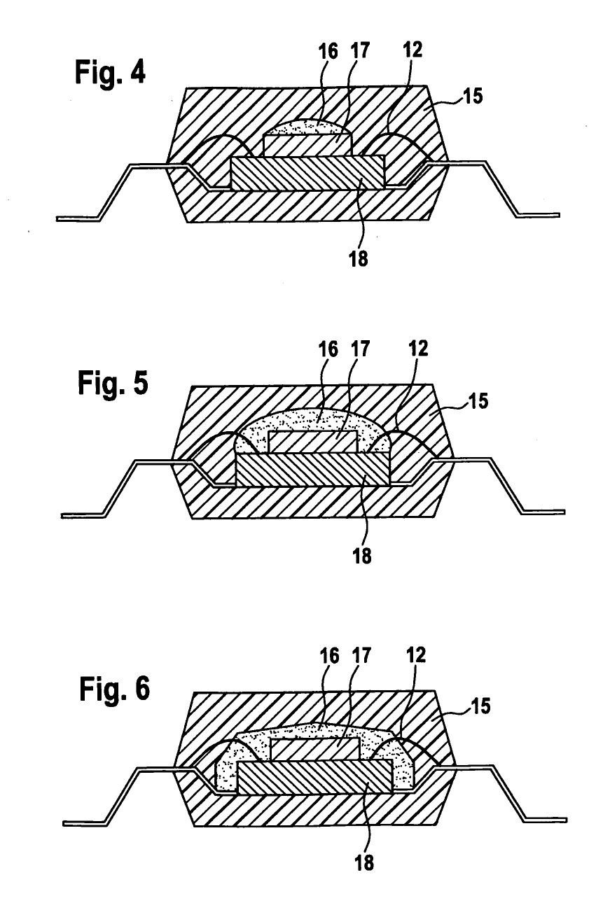

FIG. 3 shows an exemplary embodiment of a sensor component according to the present invention, the sensor element, which is developed as a micromechanical sensor element, for instance, being developed to have comb structures, for instance, vertically above which there is a carrier element. The carrier element is preferably formed by an evaluation electronic system in the form of an application-specific semiconductor element 11. As shown in FIGS. 3 and 4, sensor element 10 and carrier element 11 are connected to each other by an adhesive 13. The adhesive is advantageously formed in the shape of an elastic cushion which decouples sensitive sensor element 10 from mechanical stress, by its elastic properties. Furthermore, one may clearly see in FIG. 3 a flip-chip connection between sensor element 10 and carrier element 11, via which the electrical connection between the two components is produced.

In this specific embodiment, the cushion may be designed in such a way that mechanical stresses are compensated via the cushion which appear, for example, by different coefficients of expansion of sensor element 10 and carrier element 11 when there are thermal stresses.

Ball grid arrays, for example, have proven themselves in practice as being reliable as flip-chip connections, which are either soldered on by reflow soldering, or which take care of making a connection using an adhesive having special properties. The connecting adhesive may, for instance, be anisotropically conductive or it may contract during curing, so that the ball of the ball grid array is drawn to the corresponding opposite contact surface for the secure production of a contact. There is also the possibility of producing a connection via a nonconductive adhesive, the contacts of the sensor being provided with so-called bumps, which may, for instance, have aluminum or gold wire, which are applied in the wire bonding method and then torn off directly at the bonding location. Adhesive is applied to the substrate, in this case evaluation electronic system IC, and the chip is bonded via the adhesive. In this case, it is also important to take care of having a secure connection, by using an adhesive that shrinks during drying, so that the bumps are drawn to the contact surfaces of the semiconductor element.

FIG. 4 shows an exemplary embodiment of the sensor according to the present invention. As may be clearly seen, there are bonding wires 12 which connect the carrier element that is preferably present as semiconductor element 18 to outside contacts on chip housing 15. Sensitive sensor element 17 is situated vertically above an evaluation electronics system situated on the carrier element and is electrically connected to it. One may also clearly recognize a gel region 16 in a domelike recess of plastic housing 15, which, in the case of this exemplary embodiment, is located only on the sensor element, the gel taking care of a thermal and mechanical adjustment, so that thermal and mechanical stresses are passed directly on to plastic housing 15.

FIG. 5 shows an additional exemplary sensor component according to the present invention, the same components or components acting the same as in FIG. 4 being designated by the same reference numerals. It may be clearly recognized here that in the region of sensor element 17, and the carrier element having an evaluating semiconductor component 18, a larger gel region 16 is formed, a domelike recess in the plastic housing, which accommodates the gel, now both enclosing sensor element 17 and also completely or partially covering the surface of carrier element 18, so that both thermal stresses between these components may be compensated for via gel 16, and mechanical stresses which are guided away in optimal fashion in connection with housing 15, sensor element 17 and evaluation circuit 18.

A silicone gel, for example, may be used as an example of such a gel. It may be used because it exhibits an outstanding flowability, and is also in a position to fill up fine interstices, it having, at the same time, excellent viscous adhesion, sealing properties and resistance to liquids, and combining this with great impact resistance. Since it is soft, it may be deformed by the application of a slight pressure or a low weight. Based on the low elasticity, a stress generated by thermal expansion is reduced.

FIG. 6 shows an additional exemplary embodiment of a sensor component according to the present invention. In FIG. 6, too, components designated the same fulfill the same function as in the preceding figures.

As may be clearly seen in FIG. 6, the specific embodiment shown there has a very large gel region in comparison to FIGS. 4 and 5, and by contrast to these, the region of it accommodated in plastic housing 15 is very small. It is characteristic for this specific embodiment that both the evaluating, application-specific circuit on carrier element 18 and sensitive sensor element 17 are now surrounded by the gel, so that an optimum temperature adjustment is able to take place, and mechanical stresses which act on the sensor structure from the outside via the housing are able to be compensated for, equalized and passed on via the gel.

In summary one may say then that, based on the construction of the sensor component according to the present invention, a sensor is obtained that exhibits long-term stability, which combines great measuring accuracy with a technically simple construction and great long-term stability, the absolute values supplied by the sensor, such as acceleration values, being stable over the entire service life.

In particular, the sensor according to the present invention has the advantages that it is insensitive to influences on the part of plastics, gel, or mechanical stresses in the vicinity of the bonding wires in the signal path, which become noticeable in the form of a changed dielectric constant, of a different bonding wire separation distance, or of moisture shunting, or by very sensitive exposed bonding wires that are able to be separated mechanically. This is advantageously caused by the fact that in the region between the connection of the sensor to the evaluating semiconductor element an electrical connection according to flip-chip technology is used.

1-16. (canceled)

17. A sensor component, comprising:
a carrier element; and
a sensor element situated over the carrier element and being electrically connected to the carrier element in an intermediate region via a connecting type;
a housing surrounding the sensor element and the carrier element.

18. The sensor component as recited in claim 17, wherein an elastic buffer in the form of an adhesive cushion is situated in the intermediate region.

19. The sensor component as recited in claim 18, wherein the connecting type is implemented as a flip-chip connection.

20. The sensor component as recited in claim 18, wherein the carrier element is connected to outside contacts via bonding wires which electrically connect the carrier element all the way through the housing to outside contact surfaces.

21. The sensor component as recited in claim 18, wherein a gel is situated between at least one subsection of the sensor element and a corresponding subsection of the housing.

22. The sensor component as recited in claim 21, wherein the gel encloses the sensor element and at least partially covers a surface of the carrier element.

23. The sensor component as recited in claim 21, wherein the gel encloses the carrier element and the sensor element.

24. The sensor component as recited in claim 21, wherein the sensor element is a micromechanical sensor element.

25. The sensor component as recited in claim 21, wherein the carrier element includes an application-specific semiconductor element configured for preparing sensor signals of the sensor element.

26. A method for manufacturing a sensor, comprising:
manufacturing a sensor element;
manufacturing a carrier element;
connecting the sensor element and the carrier element to each other in flip-chip manner; and
inserting the sensor element and the carrier element into a housing.

27. The method for manufacturing a sensor as recited in claim 26, wherein the carrier element is electrically connected to outside contact surfaces via bonding wires.

28. The method for manufacturing a sensor as recited in claim 27, further comprising:
providing a gel between the housing and at least one part of the sensor element.

29. The method for manufacturing a sensor as recited in claim 28, wherein the gel encloses the sensor element and at least partially covers a surface of the carrier element.

30. The method for manufacturing a sensor as recited in claim 28, wherein the gel is situated in such a way that the gel encloses the sensor element and the carrier element.

31. The sensor as recited in claim 23, wherein the sensor is configured as an inertial sensor.
